(19) United States
(12) Patent Application Publication
(10) Pub. No.: US 2008/0002833 A1
(43) Pub. Date: Jan. 3, 2008

(54) Volume estimation by diffuse field acoustic modeling

(75) Inventor: Martin Kuster, Belfast (IE)

Correspondence Address: DTS, INC., 5171 CLARETON DRIVE, AGOURA HILLS, CA, 91301, US

(73) Assignee: DTS, Inc.

(21) Appl. No.: 11/479,477

(22) Filed: Jun. 29, 2006

(51) Int. Cl. H03G 3/00; H04R 29/00

(52) U.S. Cl. 381/63; 381/59

(57) ABSTRACT

A method and apparatus for estimating volume of an enclosed space (“room”) based on measured acoustic parameters. The method includes the steps of: measuring an acoustic impulse response of the enclosed space. From the acoustic impulse response, the method calculates the parameters: mean square pressure of reverberant sound; mean square pressure of direct sound; arrival time of direct sound; and a reverberation time parameter (T60). From those parameters, a volume estimate is calculated based on an acoustic diffuse field theoretical model.

### BACKGROUND OF THE INVENTION

1. Field of the Invention

The invention relates to audio signal processing generally, and more specifically to the characterization, simulation, and compensation of room acoustics by characterizing Room Impulse Response (RIR) of an acoustic environment.

2. Description of the Related Art

The general course in room acoustics research is to compare measurements of a room impulse response or total sound pressure to a prediction calculated from geometrical and acoustical room parameters. Among the relevant acoustical room parameters, the room volume is considered one of the most important. However, in some situations room volume is unknown and direct measurement may be inconvenient at best.

A naïve choice for the estimation of room volume would be temporal density of reflections, which is given approximately by:

$$\frac{d {N}_{t}}{d t} = 4 π \frac{{c}^{3} {t}^{2}}{V} \qquad ( Eq . 1 )$$

Where t is the time variable, c the speed of sound in air, and V the room volume. This equation is only accurate for large t, however. By counting the number of reflections in time intervals, one might expect to be able to determine room volume from equation 1 above; however, this approach fails. The problem is that Eq. 1 has been derived from geometrical acoustics and is based on reflections rather than reflected waves. Therefore, it neglects the effects of non-smooth surfaces with complex, frequency dependent and non-locally reacting acoustic impedances, all of which can cause temporal smearing. Identifying and counting reflections in a measured room impulse response (RIR) will thus be nearly impossible except for a half-dozen early reflections (during a time interval in which Eq. 1 is inaccurate).

“Diffuse field acoustics” is an approach to characterizing the acoustics of enclosed spaces, and is known to provide useful descriptions of rooms of good acoustic quality (concert halls, for example). The Diffuse field approximation is based on the assumption that the sound field resembles a composition of plane waves distributed uniformly in all directions; the model obviously is accurate only in certain situations. Conventionally this model might be used to estimate a room response based on known room parameters (as may be obtained by direct measurement); the diffuse field approximation has not been used for the reverse problem: to estimate the room parameters from a known room response.

### SUMMARY OF THE INVENTION

The invention provides a method and apparatus for estimating volume of an enclosed space (“room”) based on measured acoustic parameters. The method includes the steps of: measuring a acoustic impulse response of the enclosed space. From the acoustic impulse response, the method includes calculating the parameters: mean square pressure of reverberant sound;mean square pressure of direct sound; arrival time of direct sound; and a reverberation time parameter (T₆₀). From those parameters, a volume estimate is calculated based on an acoustic diffuse field theoretical model.

### BRIEF DESCRIPTION OF THE DRAWINGS

FIG. 1 is a block diagram showing an apparatus in accordance with the invention in context of an acoustic environment or “room”; and

FIG. 2 is a flow diagram showing steps of a method in accordance with the invention.

### DETAILED DESCRIPTION OF THE DRAWINGS

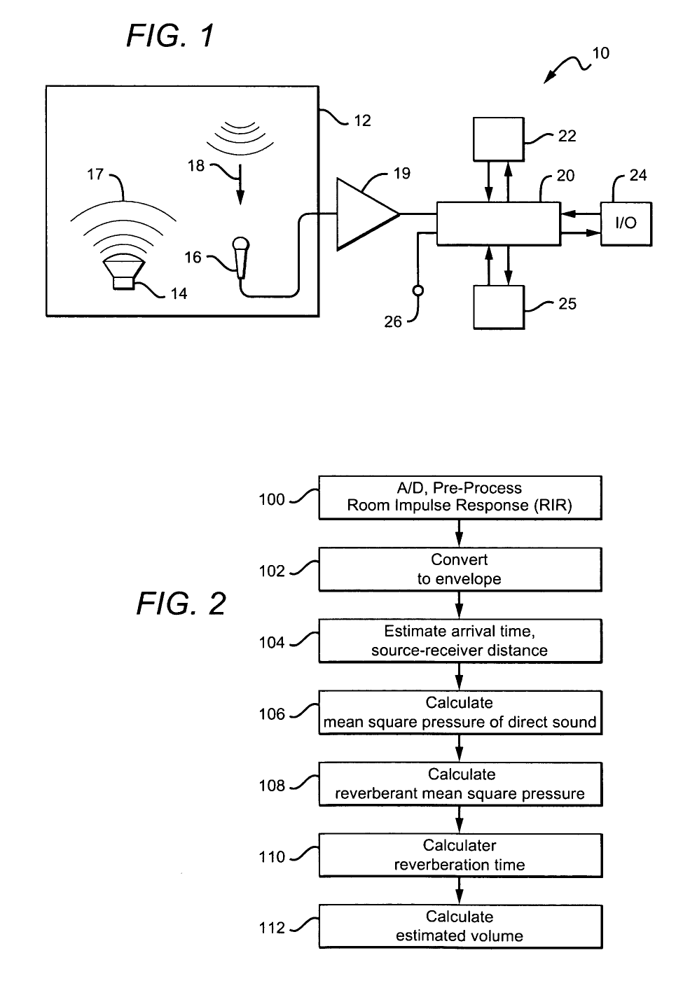

FIG. 1 shows an apparatus (generally at 10) suitable for practicing the invention, in relation to a suitable acoustic environment or “room” 12. Although the word “room” is used throughout this disclosure to refer to the acoustic environment, it should be understood that any of a variety of acoustic systems or environments could be the subject of the invention; the method is not limited to measurement of architectural or human-constructed rooms, and might be applied more generally to estimate the volume of any acoustic system.

An acoustic emitter 14 excites room 12 with an acoustic signal suitable for measuring the impulse response of the room 12. For example, an acoustic impulse or explosion may be used; alternatively, a frequency swept sine wave excitation may be used, as is known in the art for measuring an acoustic impulse response function. The acoustic response of the room interacts with a microphone or acoustic transducer 16 and is converted into an electrical signal. Both direct and reverberant sounds 17 and 18 are picked up by the microphone and converted. The signal in turn is preprocessed by pre-processing electronics module 19, which typically includes an analog to digital converter as well as preliminary signal processing modules. The processed signal (digital) is then further processed by a volume estimation engine 20, to produce a volume estimate.

The volume estimation engine 20 is suitably a general purpose digital computer, communicating with adequate random access memory (RAM) 22 for data and program memory, and with input/output devices 24 for control, and further with bulk storage 25 such as magnetic storage disk for storing signals, programs, and results. Alternatively, specialized digital signal processing (DSP) processors could be employed, either together with or instead of a general purpose microprocessor.

In some applications, the impulse response of the subject acoustical environment may by sampled in advance or remotely, then recorded or transmitted. The recorded or transmitted impulse response then substitutes for the immediately measured impulse response as input 26 into the volume estimation engine 20.

The flow diagram in FIG. 2 shows steps of the method of volume estimation in accordance with the invention.

Initially, in pre-processing step 100, a room impulse response is preferably pre- processed to simplify and improve the estimations process. The signal is initially sampled and converted to a digital signal by sampling and A/D converter circuits. Also in pre-processing, the signal is pre-filtered to select a frequency band of interest. Limiting the bandwidth is advantageous and is believed to improve the accuracy of estimation because it simplifies assumptions about source and receiver directivity. It is known that whether the source is a natural sound source or a loudspeaker, it will have a directivity that is determined by its size and geometry in relation to the varying acoustic wavelengths that are components of the emitted sound. Since the source directivity is generally unknown, it is advantageous to restrict the bandwidths of concern to those frequencies in which omni-directional characteristics can be assumed for the source. The inventors have found that an upper frequency limit of 700 Hz is appropriate. A lower frequency, for example, around 65 Hz may also be usefully introduced because at very low frequencies the response is dominated by a few dominant room modes. Modal behavior contradicts diffuse field acoustics assumptions, which will be applied in the steps of estimation (described below).

Next, in a further preprocessing step 102 the measured or recorded impulse response is converted to an envelope, for example by applying a Hilbert transform.

In step 104, the envelope of the direct sound is used to estimate an arrival time for the direct sound. In one suitable method, the arrival time of the direct sound is estimated by finding the first time sample that had power 15 dB below the maximum magnitude in the impulse response. It has been found that this method woks well regardless of whether the direct sound features the largest magnitude in the RIR.

In step 106, the mean square pressure of the direct sound is calculated as follows: the squared magnitudes in a time window extending from −1 millisecond to +1.5 millisecond (relative to the identified time of direct sound arrival) are summed. This mean-square-pressure is used as a reasonable estimate of direct sound mean square pressure.

Next, in step 108, the reverberant mean square pressure is calculated. Due to the presence of noise, the calculation of the reverberant mean square pressure is more challenging. A method known and published by Landerby may be used to estimate the cross over point between decaying RIR and stationary noise floor. Due to the insignificant magnitude, the contribution of the RIR from the cross-over point until eternity is not compensated for in the calculation of reverberant pressure; it has been found sufficient to include contributions only up to the cross over point.

Reverberation time is calculated in step 110 from the RIR (modified by filtering as described above). For purposes of the invention, a conventional measurement such as T₆₀ may be used, where T₆₀ is the time required for sound to decay by −60 decibels from its initial level.

In step 112 the room volume is estimated. The variable inputs to the estimation algorithm are (at least): reverberation time (T₆₀), mean square pressure of direct sound, mean square pressure of reverberant sound, all calculated in the preceding steps. In a simplistic model, the volume V is estimated in accordance with a relationship of the form:

$$V = \frac{\overline{{p}_{0}^{2}} ( {r}_{0} )}{\overline{{p}_{r}^{2}}} \cdot \frac{4 π {r}_{0}^{2} {cT}_{60}}{6 ln ( 10 )} \qquad ( Eq . 2 )$$

### Where

$$\overline{{p}_{0}^{2}} ( {r}_{0} )$$

is the mean square pressure of the direct sound,

$$\overline{{p}_{r}^{2}}$$

is the mean square pressure of the reverberant sound, r₀ is the source-to-receiver distance, c is the speed of sound in air, and T₆₀ is the reverberation time (time required for reverberations to decrease by 60 decibels). Note that r₀ may be determined by multiplying the speed of sound in the room by a measured arrival time.

The calculation of volume may be improved, in one embodiment of the invention, by using an alternate relationship, specifically:

$$V = \frac{\overline{{p}_{0}^{2}} ( {r}_{0} )}{\overline{{p}_{r}^{2}}} \cdot \frac{4 π {r}_{0}^{2} {cT}_{60}}{6 ln ( 10 )} \cdot [ {e}^{- {r}_{0} / c 6 ln ( 10 )} ] \qquad ( Eq . 3 )$$

This relationship makes allowance for effects observed by Barron, reported previously in M. Barron and L. J. Lee, “Energy relations in concert auditoriums, I,” J. Acoust Soc. Am. 84(2), pp. 618-628 (1988).

Optionally, also in step 112, the calculation may suitably be compensated for a known source or receiver directivity. The receiver, for example, a microphone, features a directivity usually ranging between omnidirectional and figure-eight pattern. It is possible to estimate the error in the above equations when assuming an omni-directional microphone, when in fact some other pattern was used in measuring the room impulse response. The estimated error can then be used to correct the volume estimate, for example by straightforward multiplication by a calculated correction factor representing directional gain.

More specifically, the directivity of the source or receiver may be compensated by using the relations:

$$\begin{matrix}\overline{{p}_{r}^{2}} ( {r}_{0} ) = \overline{{Q}_{mic}^{2} {Q}_{speaker}^{2}} {ρ}_{0} cW ( \frac{{T}_{60} c}{6 ln ( 10 ) V} ) \\ And & ( Eq . 4 ) \\ \overline{{p}_{0}^{2}} ( {r}_{0} ) = {{Q}^{2} ( - {r}_{0} )}_{mic} {{Q}^{2} ( {r}_{0} )}_{speaker} {ρ}_{0} cW ( \frac{1}{4 π {r}_{0}^{2}} ) & ( Eq . 5 )\end{matrix}$$

### Where Q(±r₀) is the directivity of the source (or receiver) in the direction of the receiver (source);

$$\overline{{ }_{-} {Q}^{2}}$$

its mean square value over the 4π solid angle; W is the sound power; and ρ₀ is the mass density of the medium (air). Dividing Eq. 4 by Eq. 5 and solving for V yields a modified relation. It is apparent that a compensated estimate for volume may be obtained by simply multiplying the estimate (from Eq. 2 or Eq. 3) by the correction factor:

$$\frac{\overline{{Q}_{mic}^{2} {Q}_{speaker}^{2}}}{{Q}_{mic}^{2} ( - {r}_{0} ) {Q}_{speaker}^{2} ( {r}_{0} )}$$

There is a marked difference between source and receiver directivity. Regardless whether the source is a natural sound source or a loudspeaker, it will have a directivity that is determined by its size and geometry in relation to the varying acoustic wavelength (of the sound's frequency components). Since the source directivity is generally unknown, it is preferred to restrict the bandwidth to frequencies where omni-directionality can be assumed (as previously discussed in relation to preprocessing step 100).

While the invention has been described in detail with regards to several embodiments, it should be appreciated that various modifications and/or variations may be made in the invention without departing from the scope or spirit of the invention. In this regard it is important to note that practicing the invention is not limited to the applications described herein above. Many other applications and/or alterations may be utilized provided that such other applications and/or alterations do not depart from the intended purpose of the invention. For example, and not by way of limitation, the method of the invention could be used to estimate the volume of any suitably large, bounded body of fluid, and is not limited in application to an actual room such as a concert hall.

I claim:

1. A method of estimating volume of an acoustic environment (“room”) based on measured acoustic parameters, comprising the steps:
Measuring a acoustic impulse response of said acoustic environment;
From said acoustic impulse response, calculating the parameters:
Mean square pressure of reverberant sound;
Mean square pressure of direct sound; and
A reverberation time parameter (T₆₀);
From said parameters, calculating a volume estimate based on an acoustic diffuse field theoretical model.

2. The method of claim 1, wherein said step of calculating a volume estimate comprises using an equation of the form:
$$V = \frac{\overline{{p}_{0}^{2}} ( {r}_{0} )}{\overline{{p}_{r}^{2}}} \cdot \frac{4 π {r}_{0}^{2} {cT}_{60}}{6 ln ( 10 )}$$
Where
$$\overline{{p}_{0}^{2}} ( {r}_{0} )$$
is the mean square pressure of the direct sound,
$$\overline{{p}_{r}^{2}}$$
is the mean square pressure of the reverberant sound, r₀ is the source-to-receiver distance, c is the speed of sound in air, and T₆₀ is the reverberation time required for reverberations to decrease by 60 decibels.

3. The method of claim 2, further comprising the further steps:
Pre-processing the acoustic impulse response by digital filtering.

4. The method of claim 3, wherein said acoustic impulse response is further pre-processed by converting said acoustic impulse response into a signal representing the envelope of said response.

5. The method of claim 3 wherein said pre-processing includes filtering with a bandpass filter.

6. The method of claim 1, comprising the further step of compensating for directional gain of either a microphone or a sound source having a known directional gain pattern.

7. The method of claim 1, wherein said step of calculating a volume estimate comprises using and equation of the form:
$$V = \frac{\overline{{p}_{0}^{2}} ( {r}_{0} )}{\overline{{p}_{r}^{2}}} \cdot \frac{4 π {r}_{0}^{2} {cT}_{60}}{6 ln ( 10 )} \cdot [ {e}^{- {r}_{0} / c 6 ln ( 10 )} ]$$
Where
$$\overline{{p}_{0}^{2}} ( {r}_{0} )$$
is the mean square pressure of the direct sound,
$$\overline{{p}_{r}^{2}}$$
is the mean square pressure of the reverberant sound, r₀ is the source-to-receiver distance, c is the speed of sound in air, and T₆₀ is the reverberation time required for reverberations to decrease by 60 decibels.

8. The method of claim 7, further comprising the further steps:
Pre-processing the acoustic impulse response by digital filtering.

9. The method of claim 7, wherein said acoustic impulse response is further pre-processed by converting said acoustic impulse response into a signal representing the envelope of said response.

10. The method of claim 7 wherein said pre-processing includes filtering with a bandpass filter.

11. The method of claim 7, comprising the further step of compensating for directional gain of either a microphone or a sound source having a known directional gain pattern.
